(19) United States
(12) Patent Application Publication
(10) Pub. No.: US 2026/0238172 A1
(43) Pub. Date: Aug. 13, 2026

(54) CONFIGURABLE EQUALIZING STAGE WITH EMBEDDED VARIABLE GAIN

(71) Applicant: Marvell Asia Pte Ltd, Singapore (SG)

(72) Inventors: Zushu Yan, Cupertino, CA (US); Dadian Zhou, Fremont, CA (US); Manisha Gambhir, Cupertino, CA (US); Ahmed Mostafa, San Jose, CA (US)

(73) Assignee: Marvell Asia Pte Ltd, Singapore (SG)

(21) Appl. No.: 19/536,401

(22) Filed: Feb. 11, 2026

Related U.S. Application Data
(60) Provisional application No. 63/757,680, filed on Feb. 12, 2025.

(51) Int. Cl. H03G 3/30; H03F 3/193; H04L 25/02; H04L 25/03

(52) U.S. Cl. CPC H03G 3/3042; H03F 3/193; H04L 25/0272; H04L 25/03057; H04L 25/03885

(57) ABSTRACT

An equalizing circuit for a multi-stage analog front end may include an equalizing portion and a variable gain portion. The equalizing portion includes at least one controllable impedance element to apply a configurable, frequency-dependent peaking response to an input signal. The variable gain portion is coupled to the equalizing portion, and the variable gain portion applies an overall gain to the input signal. The overall gain is independent from the peaking response of the equalizing portion.

### PRIORITY APPLICATION

This patent application claims priority to and/or receives benefit from U.S. Provisional Application No. 63/757,680, titled “Configurable CTLE Peaking Stage with Embedded VGA,” filed on Feb. 12, 2025. The U.S. Provisional Application is hereby incorporated by reference in its entirety.

### BACKGROUND

High-speed, high-bandwidth communication systems are integral to modern computing and networking applications. These systems are designed to facilitate efficient and reliable data transmission over various media or communication links, including optical fibers, copper cables, and wireless channels. Advances in communication technologies, such as improvements in analog circuit designs in an analog front-end, signal modulation, error correction, and clock recovery, can ensure data integrity, reduce latency, and maintain synchronization across devices.

### BRIEF DESCRIPTION OF THE DRAWINGS

Examples will be readily understood by the following detailed description in ‎conjunction with the accompanying drawings. To facilitate this description, like reference ‎numerals designate like structural elements. Examples are illustrated by way of ‎example, and not by way of limitation, in the figures of the accompanying drawings.

FIG. 1 illustrates a receiver architecture, according to some examples of the disclosure.

FIG. 2 illustrates an example analog front-end, according to some examples of the disclosure.

FIG. 3 illustrates a first example equalizing circuit, according to some examples of the disclosure.

FIG. 4 illustrates a second example equalizing circuit, according to some examples of the disclosure.

FIG. 5 illustrates a first set of voltage response curves of the equalizing circuit with variable gain, according to some examples of the disclosure.

FIG. 6 illustrates a second set of voltage response curves of the equalizing circuit with variable gain, according to some examples of the disclosure.

FIG. 7 depicts a flow chart illustrating a method performed by an analog front-end of a receiver, according to some examples of the disclosure.

### DETAILED DESCRIPTION

### Overview

High-speed SerDes receivers include an analog front-end (AFE) that implements one or more gain stages and one or more equalizing stages, such as a continuous-time linear equalizer (CTLE). CTLEs provide a controlled frequency-domain peaking response to compensate for channel loss at higher frequencies along with overall voltage gain. In many implementations, a CTLE is used as the first stage in an AFE, followed by one or more additional CTLEs and one or more variable gain amplifiers (VGAs). The VGAs can provide continuous gain control to address drift in gain due to temperature or voltage variations, for example.

The first CTLE stage plays a critical role in equalizing different channels. To support different data rates, it is useful to have a highly configurable peaking network that can peak at different frequencies. Typically, one or more standalone VGAs follow the first peaking stage (e.g., the first stage CTLE). These later-stage VGAs introduce noise and consume power and area. Alternatively, a VGA may be used as the first stage, followed by one or more CTLEs and one or more additional VGAs. Placing the VGA first can reduce noise; however, this interferes with equalization performance.

To address these challenges, an equalizing stage that includes an embedded variable gain element can be implemented. The equalizing stage includes an equalizing portion, e.g., a CTLE, and a variable gain portion, e.g., a VGA. Embedding the variable gain portion into the equalizing stage results in a low-noise, power- and area-efficient peaking gain structure that embeds a VGA effectively. The flexible configuration of different peaking frequencies allows the equalizer circuit with embedded variable gain to support both high data rates (e.g., above 100G) and legacy data rates (e.g., 100G or below) without disrupting the VGA function and equalization capability. In some implementations, the equalizing circuit described herein can provide robust performance for 224 Gbps SerDes systems, or even higher frequency systems.

In some examples, the equalizing circuit with integrated variable gain includes an equalizing portion and a variable gain portion. The equalizing portion includes at least one controllable impedance element to apply a configurable, frequency-dependent peaking response to an input signal. The variable gain portion is coupled to the equalizing portion, and the variable gain portion applies an overall gain to the input signal. The overall gain is independent from the peaking response of the equalizing portion.

In some examples, the equalizing circuit further includes controllable impedance elements, e.g., a controllable impedance network. The controllable impedance network enables control of the peaking frequency. The impedance network may include a set of inductors and switches, where actuating the switches changes the peaking frequency of the equalizing circuit. The impedance network may also decouple the VGA from the peaking portion of the circuit, enabling reliable peaking performance and gain across a wide frequency range.

In some examples, an analog front-end includes multiple stages, where one of the stages includes an equalizing circuit with an embedded VGA. While the equalizing circuit with embedded VGA can advantageously be used as the first stage of an AFE, as described above, in other embodiments, the equalizing circuit may alternatively or additionally be used in the second stage, third stage, or later stage(s) of the AFE. For example, the equalizing circuit with embedded VGA may be used in multiple stages, e.g., the first stage and second stage, or the first stage and third stage. In other examples, a traditional CTLE or traditional VGA may be used as the first stage, followed by the equalizing circuit with embedded VGA as the second stage, or a later stage.

The equalizing circuit described herein offers highly configurable peaking frequencies, so that the SerDes circuit can be used across a variety of applications, scaling needs, and configuration options. Embedding the VGA results in less noise, less power use, and better equalization for a given noise compared to prior AFE implementations. Noise-efficient equalization is an important metric, especially for long-reach SerDes performance. Embedding the VGA as described herein also results in reduced area penalty compared to implementations with separate VGAs. The equalizing circuit enables broadband control across a wide frequency range (e.g., across a 50 GHz or wider band). Furthermore, the equalizing circuit can be coupled with a digital signal processor (DSP) in a feedback loop that enables temperature and drift-tracking features during active operations, providing robust and stable performance in high-frequency systems.

### Example receiver architecture

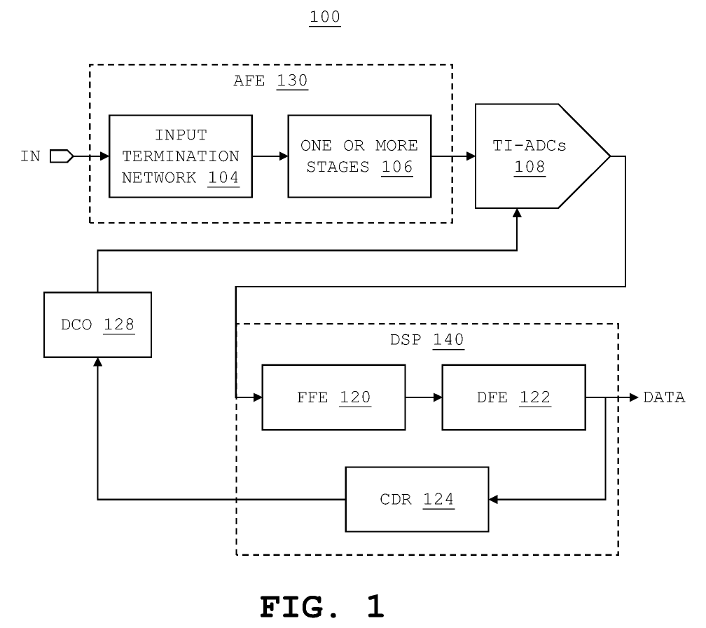

FIG. 1 illustrates receiver architecture 100, according to some examples of the disclosure. Receiver architecture 100 comprises one or more of: analog front-end (AFE) 130, time-interleaved analog-to-digital converters (TI-ADCs) 108, digital signal processor (DSP) 140, and digitally controlled oscillator (DCO) 128. Receiver architecture 100 processes an input signal shown as “IN” and outputs recovered data shown as “DATA”.

AFE 130 comprises one or more of: input termination network 104 and one or more stages 106. Input termination network 104 can include impedance matching circuitry to terminate the incoming signal IN to reduce reflections and maintain signal integrity. Input termination network 104 can include passive circuit components such as resistors, capacitors, or inductors arranged to provide impedance matching for the incoming signal. These passive circuit components help minimize reflections, maintain signal integrity, and stabilize the input interface without requiring active circuitry. One or more stages 106 can include one or more of: amplification stage(s), equalization stage(s), gain stage(s), active stage(s), and filtering stage(s) to condition the signal prior to digitization. In some examples, AFE 130 may implement gain control and bandwidth shaping in one or more stages 106 to optimize signal quality for subsequent conversion. In some examples, AFE 130 may implement a CTLE in one or more stages 106 to apply frequency-dependent gain to compensate for channel loss at high frequencies. A CTLE can boost attenuated high-frequency components while reducing low-frequency gain and improve signal integrity before analog-to-digital conversion. In some examples, AFE 130 may implement one or more analog signal conditioning stages, such as one or more of a variable gain amplifier stage, a transconductance stage, a transimpedance stage, a filtering stage, a gain stage, and an equalization stage. In some examples, a stage in AFE 130 may perform one or more functions, such as one or more of equalization, transconductance conversion, transimpedance conversion, broadband gain shaping, impedance matching, conditioning operation, and signal shaping operation. In some examples, AFE 130 may include one or more discrete stages or circuits.

TI-ADCs 108 can include multiple interleaved ADCs to sample the conditioned signal at high effective rates and perform analog-to-digital conversion. TI-ADCs 108 can operate with phase alignment and calibration mechanisms to mitigate timing mismatches and improve linearity. In some examples, TI-ADCs 108may provide digital outputs to DSP 140 for further processing. While receiver architecture 100 utilizes TI-ADCs 108, it is envisioned that other high-speed ADC architectures can be implemented to digitize the conditioned signal from AFE 130 at high data rates.

DSP 140 comprises one or more of: feed-forward equalizer (FFE) 120, decision feedback equalizer (DFE) 122, and clock and data recovery (CDR) 124. DSP 140 may receive one or more digital outputs from TI-ADCs 108 and output processed/recovered data (“DATA”) for further processing.

FFE 120 can include a set of filter taps configured to compensate for channel impairments such as inter-symbol interference (ISI) by applying a linear correction to the digitized signal. In some examples, FFE 120 may adapt its coefficients based on error feedback.

DFE 122 can include feedback taps configured to cancel post-cursor ISI by subtracting estimated interference from previously detected symbols. DFE 122 can operate in conjunction with FFE 120 to improve overall signal fidelity. In some examples, DFE 122 may employ adaptive algorithms to optimize tap weights dynamically.

CDR 124 can include phase detectors and loop filters to recover timing information from the incoming data stream. CDR 124 can generate a recovered clock signal used to align sampling and data decisions. In some examples, CDR 124 may provide one or more control signals to DCO 128 for frequency adjustment.

DCO 128 can generate a local clock signal for sampling and synchronization. The local clock signal is used to drive sampling by and operation of TI-ADCs108. DCO 128 can receive control inputs from CDR 124 to adjust its frequency and phase. In some examples, DCO 128 may support fine-grained tuning for jitter reduction and timing accuracy.

### Example of analog front-end circuitry

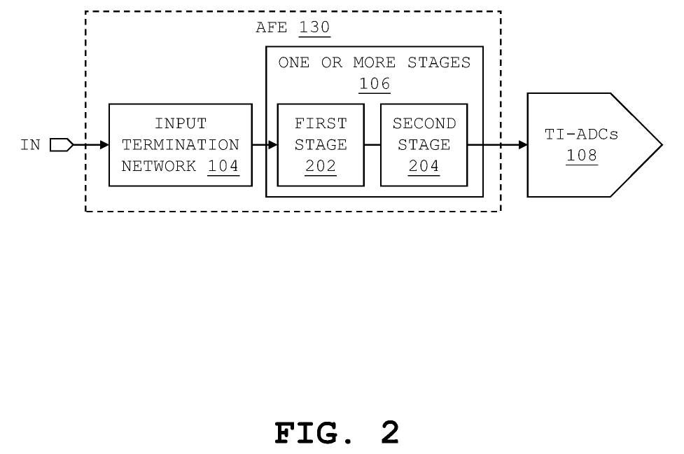

FIG. 2 illustrates an example implementation of AFE 130, according to some examples of the disclosure. One or more stages 106 can include one or more of: a first stage 202 and a second stage 204. The two-stage design is illustrative, and one or more stages 106 can include one stage or more than three stages, depending on the application.

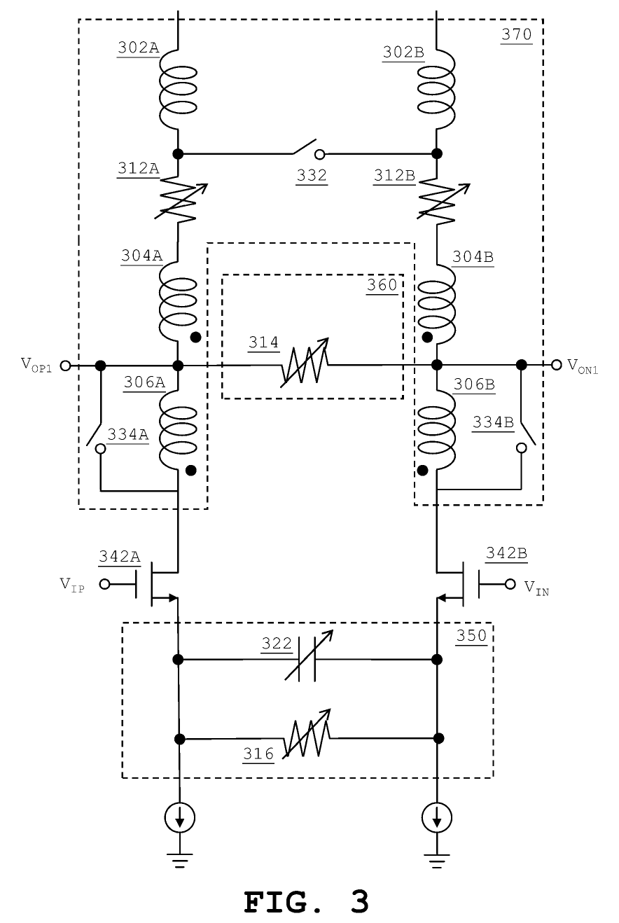

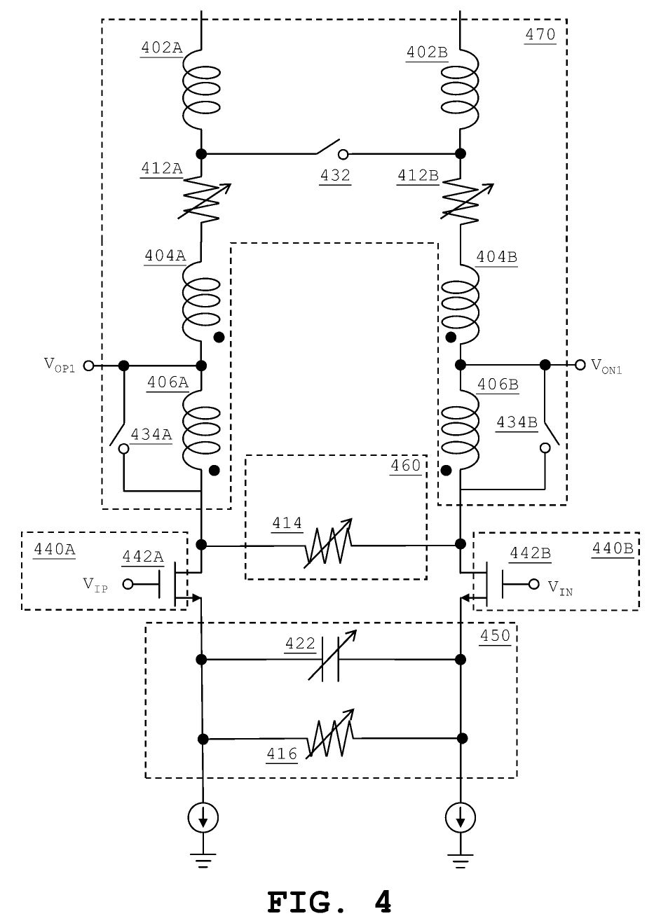

In some examples, the first stage 202 includes an equalizing circuit with an embedded VGA, such as the equalizing circuit illustrated in FIGS. 3 or 4. The equalizing circuit enhances high‑frequency gain while also boosting the overall gain of the input signal. The equalizing circuit may further include an inductive network with one or more T-coils. The inductive network further extends bandwidth by splitting and absorbing parasitic capacitances at the load nodes, allowing the stage to maintain a well‑terminated, broadband response even under heavy channel loss. Together, these circuit components form a resonant peaking structure that boosts the high‑frequency components of the incoming signal, providing substantial front‑end equalization, and also boosts the overall signal by a variable amount using an embedded VGA.

The second stage 204 and one or more further stages may provide additional gain or signal shaping, e.g., more selective signal shaping. In some examples, the second stage 204 may be implemented using an equalizing circuit with an embedded VGA, such as the equalizing circuit shown in FIGS. 3 or 4. In some examples, the second stage 204 may include a CTLE circuit, such as an asymmetric push-pull Gm stage that feeds a TIA-like load with inductive-resistive feedback. The push-pull Gm stage as a Gm circuit offers benefits of high linearity and power efficiency. The second stage 204 can integrate a peaking network, comprising a network of resonance peaking with broadband gain controls. Specifically, the peaking network can compensate for channel loss and tailor peaking characteristics and equalization profile to optimize signal conditioning before digitization. In other examples, the second stage 204 can be a variable gain circuit, e.g., a VGA. The AFE 130 can support a wide range of equalization and optimize the downstream ADC (e.g., TI-ADC) dynamic range utilization in mission mode. In particular, the second stage 204 can set the signal amplitude and spectral shape so the downstream ADC uses as much of its range as possible.

FIG. 2 further illustrates two control signals 212 and 214 for the first stage 202 and second stage 204, respectively. In some embodiments, only a subset of the stages of the one or more stages 106 receives a control signal. The control signal 212 or 214 may be a feedback signal from the DSP 140. For example, if the first stage 202 includes variable impedance elements (e.g., a variable resistor and/or variable capacitor), the control signal 212 may be a signal for selecting an impedance, e.g., to select a resistor from a resistance bank, or to enable one or more capacitors from a capacitor array.

### Example equalizing circuits for analog front-end circuitry

FIG. 3 illustrates an example circuit implementation of an equalizing circuit 300 that may be used in the AFE 130, e.g., as the first stage 202 and/or the second stage 204.

The equalizing circuit 300 includes an equalizing portion 350 and a variable gain portion 360. The equalizing portion 350 includes at least one controllable impedance element to apply a configurable, frequency-dependent peaking response to an input signal. The variable gain portion 360 is coupled to the equalizing portion. The variable gain portion 360 is configured to apply an overall gain to the input signal. The overall gain applied by the variable gain portion 360 is independent from the peaking response of the equalizing portion 350.

In this example, a differential input signal V_{IP} and V_{IN} is received at the gate terminals of a pair of transistors 342A and 342B. The sources of the transistors 342A and 342B are coupled to the equalizing portion 350. The equalizing portion 350 includes a variable capacitive element, e.g., variable capacitor 322, and a variable impedance element, e.g., variable resistor 316. The variable capacitor 322 is arranged in parallel with the variable resistor 316.

The variable gain portion 360 includes at least one controllable impedance element that is configured to adjust an overall gain of the equalizing circuit 300. In this example, the variable gain portion 360 includes a variable resistor 314. For example, variable resistor 314 may be implemented as a switched-resistor bank, a MOSFET operated in a linear region, or another implementation that provides controllable impedance.

The controllable impedance element of the variable gain portion 360 is arranged between and coupled to differential output nodes V_{OP} and V_{ON1} of the equalizing circuit 300. In this example, the variable resistor 314 is directly coupled to the differential output nodes V_{OP} and V_{ON1}. In another embodiment, shown in FIG. 4, the variable gain portion is positioned below the inductors 306A and 306B and switches 334A and 334B, and, depending on the setting of the switches 334A and 334B, the variable gain portion may not be coupled directly to the differential output nodes.

The variable resistor 314 may be responsive to a gain-control signal that adjusts the effective resistance of the controllable impedance element (e.g., by selecting a resistive segment of a switched-resistor bank, or biasing a MOSFET) to set the overall gain applied by the equalizing circuit 300. The gain-control signal may be provided by the DSP 140, which may be configured to track drift in the overall gain or equalization response and adjust the gain-control signal accordingly. In particular, the DSP 140 may be arranged in a feedback loop with the equalizing circuit 300, where the DSP 140 is configured to track variations in the gain or frequency response arising from, e.g., temperature changes, device aging, voltage changes, or other drift mechanisms, and to update the gain-control signal in a feedback loop so that the effective resistance of the variable resistor 314 is continually adjusted to maintain stable and accurate gain.

In this example, the equalizing circuit 300 further includes an inductive network 370. The inductive network 370 provides a frequency-dependent load within the equalizing circuit 300. The inductive network 370 shapes how signals transition from the equalizing portion 350 toward the variable gain portion 360 and ultimately toward the output nodes V_{OP} and V_{ON1}. The inductive network 370 decouples the equalizing portion 350 from the variable gain portion 360, thereby reducing undesired interaction between their respective impedance domains and providing stable peaking and gain characteristics.

The inductive network 370 includes multiple inductive elements, e.g., the inductors 302A, 302B, 304A, 304B, 306A, and 306B. In this implementation, the inductive network 370 further includes variable resistive elements 312A and 312B. The inductive network 370 may further include one or more switches, e.g., the switches 332, 334A, and 334B, that can be actuated to adjust the inductive network 370, e.g., to alter a peaking frequency of the equalizing circuit 300.

More specifically, the inductive network 370 shown in FIG. 3 includes one switchable inductive element (represented as inductor 306A) coupled to a first node V_{OP1} of a differential output pair, and a second switchable inductive element (represented as inductor 306B) coupled to a second node V_{OP2} of the differential output pair. The inductors 306A and 306B may be magnetically coupled inductors, providing mutual inductance. The switches 334A and 334B can be closed to couple the output nodes V_{OP1} and V_{OP2} directly to the drain terminals of the transistors 342A and 342B, respectively, thereby bypassing the inductors 306A and 306B.

Above the output nodes V_{OP1} and V_{OP2} and the variable gain portion 360, the inductive network 370 includes additional inductive elements, e.g., inductors 302A, 302B, 304A, and 304B, and variable resistive elements, e.g., variable resistors 312A and 312B. Inductors 304A and 304B may be magnetically coupled inductors, providing mutual inductance. Inductors 302A and 304A and variable resistor 312A are coupled between the output node V_{OP1} and power supply 380, and inductors 302B and 304B and variable resistor 312B are coupled between the output node V_{OP2} and the power supply 380. As noted above, the variable gain portion 360 of the equalizing circuit 300 is coupled between the first node and the second node of the differential output pair V_{OP1} and V_{OP2}.

In addition to the switches 334A and 334B, the inductive network 370 includes an additional switch 332 connecting a first internal node between the inductor 302A and the variable resistor 312A to a second internal node between the inductor 302B and the variable resistor 312B. The switches 332, 334A, and 334B are operable to adjust a peaking frequency of the equalizing circuit. Closing the switch 332 may result in a higher peaking frequency, suitable for higher frequency signals. Closing the switch 332 shorts across the inductors 302A and 302B, removing their inductive loading from the signal path and thereby shifting the resonant or peaking frequency of the equalizing circuit 300 upward. On the other hand, when the switch 332 is open, the inductors 302A and 302B are in the circuit, leading to a higher inductance in the inductive network 370 and lowering the peaking frequency.

As noted above, closing switches 334A and 334B bypasses the inductors 306A and 306B, which reduces the effective inductance of the inductive network 370 and increases the peaking frequency for high‑frequency operation. In some applications, the switches 332, 334A, and 334B are operated in tandem, e.g., the switches 332, 334A, and 334B are open for lower-frequency signals, and closed for higher-frequency signals. In some applications, the switch 332 may be operated independently from the switches 334A and 334B, so that the switch 332 may be closed while the switches 334A and 334B are opened, or vice versa, to provide intermediate peaking characteristics. More generally, different combinations of settings of the switches 332, 334A, and 334B can provide different peaking frequencies, which may be used to equalize various channels at different data rates.

FIG. 4 illustrates a second example equalizing circuit 400, according to some examples of the disclosure. The equalizing circuit 400 in FIG. 4 includes an equalizing portion 450 with a variable resistor 416 and variable capacitor 422, which are similar to the equalizing portion 350 with the variable resistor 316 and the variable capacitor 322 of equalizing circuit 300. The equalizing circuit 400 also includes a variable gain portion 460 and an inductive network 470, which are similar to the variable gain portion 360 and inductive network 370 of FIG. 3, except the placement of variable gain portion 460 is different from the placement in FIG. 3. In the equalizing circuit 400, the variable gain portion 460 is below the inductive network 470 and directly connected between a pair of input circuit elements 440A and 440B.

In this example, the equalizing circuit 400 includes a first input circuit element 440A that includes the transistor 442A, which is similar to the transistor 342A, and a second input circuit element 440B that includes the transistor 442B, which is similar to the transistor 342B. The differential input signal V_{IP} and V_{IN} is received at the gate terminals of the transistors 442A and 442B. The sources of the transistors 442A and 442B are coupled to the equalizing portion 450. The drain terminals of the transistors 442A and 442B are coupled to the variable gain portion 460, in this case, to either side of the variable resistor 414. The drain terminals of the transistors 442A and 442B are also coupled to the inductive network 470. In particular, the drain terminals of the transistors 442A and 442B are coupled below the inductors 406A and 406B, each of which is arranged in parallel with a respective switch 434A and 434B, in a similar manner to FIG. 3. The opposite sides of the switches 434A and 434B and the inductors 406A and 406B are coupled to the differential output nodes V_{OP1} and V_{OP2}. The upper portion of the inductive network 470, including inductors 402A and 402B, variable resistors 412A and 412B, inductors 404A and 404B, and switch 432, are similar to the upper portion of the inductive network 370 of FIG. 3.

Either of the equalizing circuits 300 or 400 may be implemented as a stage of a multi-stage AFE, e.g., as the first stage 202 or the second stage 204 of the AFE 130 illustrated in FIGS. 1 and 2. In some embodiments, multiple stages of the AFE 130 may be implemented as an equalizing circuit with an embedded VGA, e.g., the AFE 130 may include two or more instances of the equalizing circuit 300 or the equalizing circuit 400 connected in series.

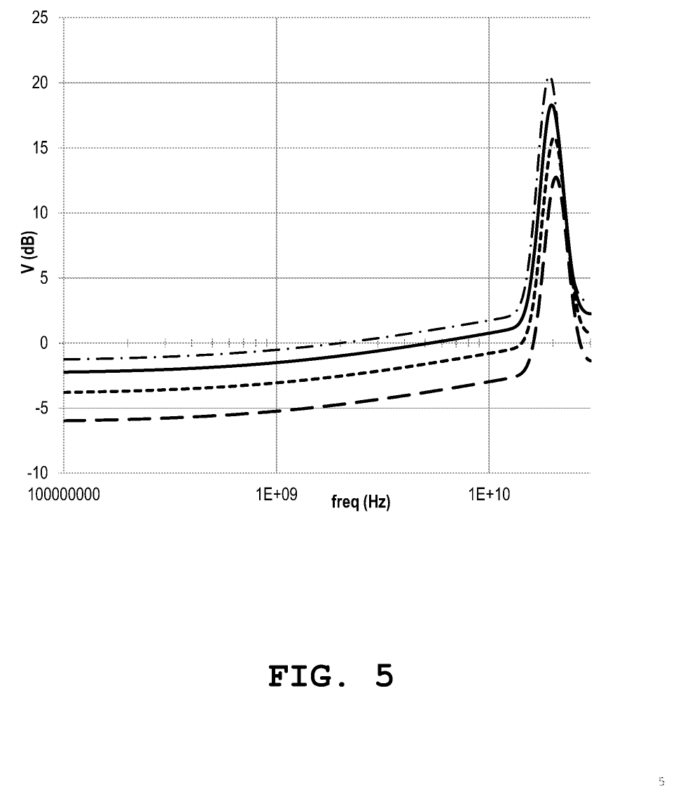

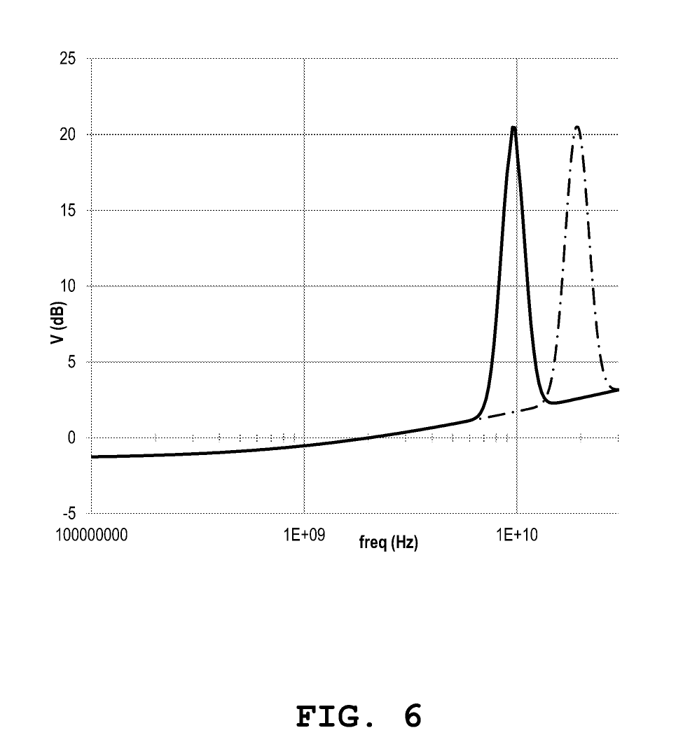

More generally, a multi-stage AFE may include, in at least one of the stages, an equalizing circuit that includes at least one controllable impedance element and a VGA. The at least one controllable impedance element applies a configurable, frequency-dependent peaking response to an input signal. Example controllable impedance elements are illustrated as equalizing portion 350 of FIG. 3 and equalizing portion 450 of FIG. 4. Example frequency-dependent peaking responses are illustrated in FIGS. 5 and 6, described below. The VGA is embedded in the equalizing circuit and applies an overall gain to the input signal, where the overall gain is independent from the peaking response. Examples of different gains that can be applied by the VGA are illustrated in FIG. 5, described below.

In some embodiments, the equalizing circuit with at least one controllable impedance element and a VGA is implemented as a first stage of a multi-stage AFE. In some embodiments, a second stage after the first stage of the AFE includes an equalizing circuit (e.g., a circuit that applies a configurable, frequency-dependent peaking response to an input signal) and does not include an embedded VGA. For example, the second stage may be a standard CTLE. In some embodiments, a second stage after the first stage of the AFE includes a variable amplifier without an equalizer. For example, the second stage may be a transimpedance amplifier (TIA).

### Example voltage response curves

FIG. 5 illustrates a first set of voltage response curves of the equalizing circuit with variable gain, according to some examples of the disclosure. FIG. 5 includes four curves, each of which may be associated with a different gain setting of a variable gain portion 360 or variable gain portion 460 of the equalizing circuit 300 or 400. In FIG. 5, the horizontal axis represents signal frequency on a logarithmic scale. The vertical axis represents the small-signal differential voltage gain of the equalizing circuit, expressed in decibels. Each curve corresponds to a respective gain configuration of the variable gain portion (e.g., variable gain portion 360 or 460). Within each curve, as frequency increases, the curves exhibit the characteristic behavior of a frequency-dependent peaking stage: a relatively flat low-frequency region, followed by a rising mid-band response that reaches a pronounced peak, and then a gradual roll-off at higher frequencies.

The four curves illustrate how the overall front-end gain can be shifted upward or downward using the embedded VGA while maintaining substantially the same peaking-frequency region for a given configuration of the equalizing portion. The variation in amplitude among the four curves demonstrates the effect of selecting different gain settings of the embedded variable gain portion 360 or 460. Higher gain settings proportionally elevate the entire response across the frequency band, whereas lower gain settings shift the response downward while preserving the shape of the equalization profile. FIG. 5 illustrates that the equalizing circuit 300 or equalizing circuit 400 can provide broadband gain control without substantially altering an intended frequency-dependent peaking characteristic. This capability enables the equalizing circuit 300 or 400 to accommodate a wide operational bandwidth while maintaining consistent equalization behavior across different gain modes.

FIG. 6 illustrates a second set of voltage response curves of the equalizing circuit with variable gain, according to some examples of the disclosure. Similar to FIG. 5, the horizontal axis represents signal frequency on a logarithmic scale, while the vertical axis represents the differential voltage gain in decibels. In FIG. 6, however, each curve corresponds to a different configuration of the switches in the inductive network (e.g., switches 332, 334A, and 334B in inductive network 370 or switches 432, 434A, and 434B in inductive network 470), which changes the effective inductance seen at the load and therefore shifts the peaking frequency of the equalizing circuit 300 or 400. For example, when one or more switches are opened, additional inductive elements (such as inductors 302A/302B and/or 306A/306B, or inductors 402A/402B and/or 406A/406B) remain in the signal path, resulting in a higher total inductance and correspondingly lower peaking frequency. When some or all of the switches are closed, selected inductors are bypassed or magnetically coupled sections are shorted, reducing the effective inductance and shifting the resonant frequency upward. Accordingly, the curves of FIG. 6 show distinct peaks at different frequencies, illustrating how actuating the switches in the inductive network enables programmable, frequency-dependent peaking behavior independent of the VGA gain setting.

### Examples of methods performed by analog front-end circuitry

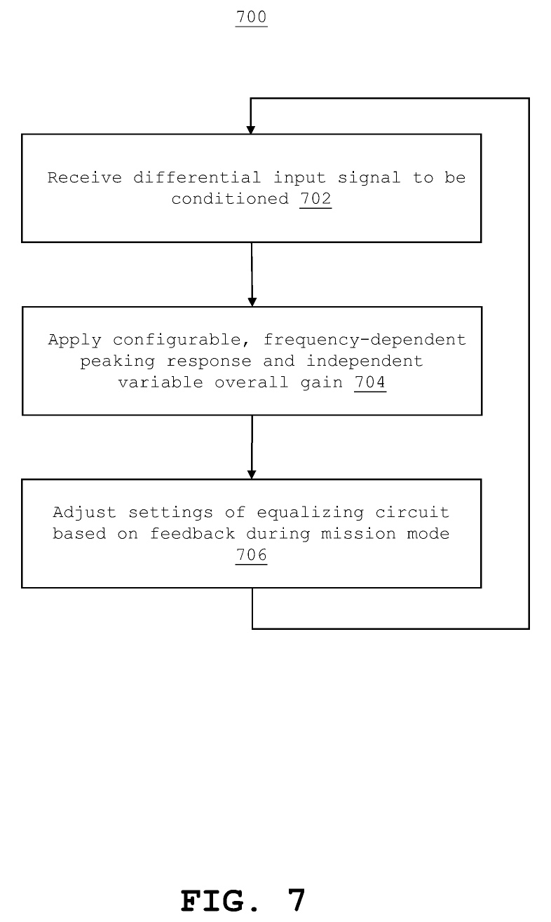

FIG. 7 depicts a flow chart illustrating method 700 performed by an analog front-end of a receiver, according to some examples of the disclosure.

In 702, an equalizing circuit (e.g., equalizing circuit 300 or 400) receives a differential input signal to be conditioned. For example, the differential input signal V_{IP} and V_{IN} is received at input circuit elements, e.g., transistors 342 or transistors 442, of the equalizing circuit.

In 704, an equalizing portion (e.g., equalizing portion 350 or 450) applies a configurable, frequency-dependent peaking response to the differential input signal based on one or more controllable impedance elements, such as switchable inductive elements, variable resistive elements, or variable capacitive elements, and a variable gain portion (e.g., variable gain portion 360 or 460) applies an overall gain to the differential input signal, where the overall gain of the variable gain portion is independent from the peaking response of the equalizing portion.

During an initial configuration phase, the method may include actuating one or more switches within an inductive network to select a desired peaking-frequency setting. The configuration phase may further include selecting a gain setting of the variable gain portion to achieve a desired signal amplitude at the output nodes.

During mission mode (i.e., during active operations), the receiver architecture 100 can dynamically adjust the configuration of the equalizing circuit 300 or 400 in response to changes in channel conditions, data-rate requirements, temperature drift, or other operating variations. In 706, the equalizing circuit adjusts settings based on feedback during mission mode. For example, DSP 140 may monitor one or more performance metrics, such as gain, equalization level, eye-opening, or amplitude margin, and update one or more control signals to the equalizing circuit. The control signals may modify the gain setting of the variable gain portion. These adjustments may be performed autonomously by a feedback loop including the DSP 140, which provides updated control signals to maintain stable gain and consistent peaking behavior throughout normal operation. The method continues, in 702 and 704, to receive differential input signals, apply the frequency-dependent peaking response and overall gain, and output a conditioned differential output signal that exhibits the desired amplitude, spectral shaping, and high-frequency equalization for reliable downstream processing.

### Select Examples

Example 1 provides an equalizing circuit with integrated variable gain, the equalizing circuit including an equalizing portion including at least one controllable impedance element to apply a configurable, frequency-dependent peaking response to an input signal; and a variable gain portion coupled to the equalizing portion, the variable gain portion to apply an overall gain to the input signal, where the overall gain is independent from the peaking response of the equalizing portion.

Example 2 provides the equalizing circuit of example 1, where the variable gain portion includes an additional controllable impedance element configured to adjust the overall gain.

Example 3 provides the equalizing circuit of example 2, where the additional controllable impedance element is coupled between differential output nodes of the equalizing circuit.

Example 4 provides the equalizing circuit of example 3, where the variable gain portion is directly coupled to the differential output nodes.

Example 5 provides the equalizing circuit of example 3, where the variable gain portion is directly coupled between a pair of differential input circuit elements.

Example 6 provides the equalizing circuit of any of examples 1-5, where the variable gain portion is configured to receive a control signal from a digital signal processor (DSP) in a feedback loop with the equalizing circuit, the control signal to set the overall gain applied to the input signal.

Example 7 provides the equalizing circuit of example 6, where the feedback loop is configured to maintain the overall gain across voltage or temperature variations.

Example 8 provides the equalizing circuit of any preceding example, the equalizing circuit further including an inductive network including a plurality of inductors.

Example 9 provides the equalizing circuit of example 8, where the inductive network includes at least one switch, where actuating the at least one switch alters a peaking frequency of the equalizing circuit.

Example 10 provides the equalizing circuit of any preceding example, where the equalizing portion includes a variable resistance element and a variable capacitive element.

Example 11 provides the equalizing circuit of example 10, where the variable resistance element is arranged in parallel with the variable capacitive element.

Example 12 provides the equalizing circuit of any preceding example, where the equalizing circuit is a single stage of a multi-stage analog front-end (AFE).

Example 13 provides the equalizing circuit of example 12, where the equalizing circuit is a first stage of the multi-stage AFE.

Example 14 provides the equalizing circuit of example 12 or 13, where the multi-stage AFE includes a second instance of the equalizing circuit as another stage of the multi-stage AFE.

Example 15 provides an equalizing circuit with integrated variable gain, the equalizing circuit including an equalizing portion including at least one controllable impedance element, where the equalizing portion is configured to apply a configurable, frequency-dependent peaking response to an input signal; a variable gain portion coupled to the equalizing portion, the variable gain portion configured to apply an overall gain to the input signal, where the overall gain is independent from the peaking response of the equalizing portion; and an inductive network configured to decouple the equalizing portion from the variable gain portion of the equalizing circuit.

Example 16 provides the equalizing circuit of example 15, where the inductive network includes a first switchable inductive element coupled to a first node of a differential output pair and a second switchable inductive element coupled to a second node of the differential output pair.

Example 17 provides the equalizing circuit of example 16, where the inductive network further includes a first inductor and a first variable resistor coupled between the first node of the differential output pair and a power supply, and a second inductor and a second variable resistor coupled between the second node of the differential output pair and the power supply.

Example 18 provides the equalizing circuit of example 16 or 17, where the variable gain portion of the equalizing circuit is coupled between the first node and the second node of the differential output pair.

Example 19 provides the equalizing circuit of any of examples 15-18, where the inductive network further includes a plurality of switches operable to adjust a peaking frequency of the equalizing circuit.

Example 20 provides an analog front-end (AFE) including a plurality of stages, where one of the stages includes an equalizing circuit including at least one controllable impedance element to apply a configurable, frequency-dependent peaking response to an input signal; and a variable gain amplifier (VGA) embedded in the equalizing circuit, the VGA to apply an overall gain to the input signal, where the overall gain is independent from the peaking response.

Example 21 provides the AFE of example 20, where the equalizing circuit and embedded VGA are a first stage of the AFE.

Example 22 provides the AFE of example 21, where the plurality of stages includes a second stage after the first stage, the second stage including an equalizing circuit without a VGA.

Example 23 provides the AFE of example 21, where the plurality of stages includes a second stage after the first stage, the second stage including a transimpedance amplifier.

Example 24 provides an equalizing circuit with integrated variable gain, the equalizing circuit including means for applying a peaking response to an input signal, where the peaking response is configurable; and means for applying an overall gain to the input signal, where the overall gain is independent from the peaking response.

Example 25 provides the equalizing circuit of example 24, where the means for applying the peaking response includes at least one controllable impedance element.

Example 26 provides the equalizing circuit of example 24 or 25, further including means for adjusting the overall gain applied to the input signal.

Example 27 provides the equalizing circuit of example 26, further including means for receiving a control signal, the control signal to set the overall gain applied to the input signal.

Example 28 provides the equalizing circuit of any of examples 24-27, further including means for adjusting a peaking frequency of the peaking response.

### Variations and other notes

The detailed description, such as the "Select examples" section, provides various examples of the examples disclosed herein.

As used herein, the term "coupled to" or "coupled with" refers to a relationship between electronic components or circuit elements wherein the components are in electronic communication with one another and are capable of transmitting and/or receiving electrical signals between them. The term "coupled to" does not require a direct physical or electrical connection between the coupled components. Rather, "coupled to" can encompass arrangements where the components are connected through one or more intervening elements, components, circuits, or transmission paths. For example, a first component may be "coupled to" a second component through intermediate components such as resistors, capacitors, inductors, transistors, logic gates, buses, transformers, or other electronic components, or through intermediate transmission paths, while still maintaining the capability for electronic communication between the first and second components.

The description of illustrated implementations herein, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations.

Further, references are made to the accompanying drawings that form a part hereof, and in which are shown, by way of illustration, examples that may be practiced. It is to be understood that other examples may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described example. Various additional operations may be performed or described operations may be omitted in additional examples.

For the purposes of the present disclosure, the phrase “A or B” or the phrase "A and/or B" means (A), (B), or (A and B). For the purposes of the present disclosure, the phrase “A, B, or C” or the phrase "A, B, and/or C" means (A), (B), (C), (A and B), (A and C), (B and C), or (A, B, and C). The term "between," when used with reference to measurement ranges, is inclusive of the ends of the measurement ranges. For the purposes of the present disclosure, the phrase “one or more of A, B, and C”, the phrase "at least one of A, B, and C", or the phrase "at least one or more of A, B, and C" means (A), (B), (C), (A and B), (A and C), (B and C), or (A, B, and C). The term "between," when used with reference to measurement ranges, is inclusive of the ends of the measurement ranges.

The description uses the phrases "in an example" or "in examples," which may each refer to one or more of the same or different examples. The terms "comprising," "including," "having," and the like, as used with respect to examples of the present disclosure, are synonymous. The disclosure may use perspective-based descriptions such as "above," "below," "top," "bottom," and "side" to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking, or in any other manner.

The terms “substantially,” “close,” “approximately,” “near,” and “about,” generally refer to being within +/- 20% of a target value as described herein or as known in the art. Similarly, terms indicating orientation of various elements, e.g., “coplanar,” “perpendicular,” “orthogonal,” “parallel,” or any other angle between the elements, generally refer to being within +/- 5-20% of a target value as described herein or as known in the art.

In addition, the terms “comprise,” “comprising,” “include,” “including,” “have,” “having,” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods, and devices of this disclosure each have several innovative aspects, no single one of which is solely responsible for all desirable attributes disclosed herein. Details of one or more implementations of the subject matter described in this specification are set forth in the description and the accompanying drawings.

1. An equalizing circuit with integrated variable gain, the equalizing circuit comprising:
an equalizing portion comprising at least one controllable impedance element to apply a configurable, frequency-dependent peaking response to an input signal; and
a variable gain portion coupled to the equalizing portion, the variable gain portion to apply an overall gain to the input signal, wherein the overall gain is independent from the peaking response of the equalizing portion.

2. The equalizing circuit of claim 1, wherein the variable gain portion comprises an additional controllable impedance element configured to adjust the overall gain.

3. The equalizing circuit of claim 2, wherein the additional controllable impedance element is coupled between differential output nodes of the equalizing circuit.

4. The equalizing circuit of claim 3, wherein the variable gain portion is directly coupled to the differential output nodes.

5. The equalizing circuit of claim 3, wherein the variable gain portion is directly coupled between a pair of differential input circuit elements.

6. The equalizing circuit of claim 1, wherein the variable gain portion is configured to receive a control signal from a digital signal processor (DSP) in a feedback loop with the equalizing circuit, the control signal to set the overall gain applied to the input signal.

7. The equalizing circuit of claim 6, wherein the feedback loop is configured to maintain the overall gain across voltage or temperature variations.

8. The equalizing circuit of claim 1, the equalizing circuit further comprising an inductive network comprising a plurality of inductors.

9. The equalizing circuit of claim 8, wherein the inductive network comprises at least one switch, wherein actuating the at least one switch alters a peaking frequency of the equalizing circuit.

10. The equalizing circuit of claim 1, wherein the equalizing portion comprises a variable resistance element and a variable capacitive element.

11. The equalizing circuit of claim 10, wherein the variable resistance element is arranged in parallel with the variable capacitive element.

12. The equalizing circuit of claim 1, wherein the equalizing circuit is a single stage of a multi-stage analog front-end (AFE).

13. The equalizing circuit of claim 12, wherein the equalizing circuit is a first stage of the multi-stage AFE.

14. The equalizing circuit of claim 12, wherein the multi-stage AFE comprises a second instance of the equalizing circuit as another stage of the multi-stage AFE.

15. An equalizing circuit with integrated variable gain, the equalizing circuit comprising:
an equalizing portion comprising at least one controllable impedance element, wherein the equalizing portion is configured to apply a configurable, frequency-dependent peaking response to an input signal;
a variable gain portion coupled to the equalizing portion, the variable gain portion configured to apply an overall gain to the input signal, wherein the overall gain is independent from the peaking response of the equalizing portion; and
an inductive network configured to decouple the equalizing portion from the variable gain portion of the equalizing circuit.

16. The equalizing circuit of claim 15, wherein the inductive network comprises a first switchable inductive element coupled to a first node of a differential output pair and a second switchable inductive element coupled to a second node of the differential output pair.

17. The equalizing circuit of claim 16, wherein the inductive network further comprises a first inductor and a first variable resistor coupled between the first node of the differential output pair and a power supply, and a second inductor and a second variable resistor coupled between the second node of the differential output pair and the power supply.

18. The equalizing circuit of claim 16, wherein the variable gain portion of the equalizing circuit is coupled between the first node and the second node of the differential output pair.

19. The equalizing circuit of claim 15, wherein the inductive network further comprises a plurality of switches operable to adjust a peaking frequency of the equalizing circuit.

20. An analog front-end (AFE) comprising a plurality of stages, wherein one of the stages comprises:
an equalizing circuit comprising at least one controllable impedance element to apply a configurable, frequency-dependent peaking response to an input signal; and
a variable gain amplifier (VGA) embedded in the equalizing circuit, the VGA to apply an overall gain to the input signal, wherein the overall gain is independent from the peaking response.

21. The AFE of claim 20, wherein the equalizing circuit and embedded VGA are a first stage of the AFE.

22. The AFE of claim 21, wherein the plurality of stages comprises a second stage after the first stage, the second stage comprising an equalizing circuit without a VGA.

23. The AFE of claim 21, wherein the plurality of stages comprises a second stage after the first stage, the second stage comprising a transimpedance amplifier.

24. An equalizing circuit with integrated variable gain, the equalizing circuit comprising:
means for applying a peaking response to an input signal, wherein the peaking response is configurable; and
means for applying an overall gain to the input signal, wherein the overall gain is independent from the peaking response.

25. The equalizing circuit of claim 24, wherein the means for applying the peaking response comprises at least one controllable impedance element.

26. The equalizing circuit of claim 24, further comprising means for adjusting the overall gain applied to the input signal.

27. The equalizing circuit of claim 26, further comprising means for receiving a control signal, the control signal to set the overall gain applied to the input signal.

28. The equalizing circuit of claim 24, further comprising means for adjusting a peaking frequency of the peaking response.
